(19) United States
(12) Patent Application Publication
(10) Pub. No.: US 2011/0308584 A1
(43) Pub. Date: Dec. 22, 2011

(54) SURFACE TREATMENT OF TRANSPARENT CONDUCTIVE MATERIAL FILMS FOR IMPROVEMENT OF PHOTOVOLTAIC DEVICES

(75) Inventors: Pratik P. Joshi, Cliffside Park, NJ (US); Young-Hee Kim, Mohegan Lake, NY (US); Steven E. Steen, Peekskill, NY (US)

(73) Assignee: INTERNATIONAL BUSINESS MACHINES CORPORATION, Armonk, NY (US)

(21) Appl. No.: 12/816,681

(22) Filed: Jun. 16, 2010

(51) Int. Cl. H01L 31/00; H01L 31/18

(52) U.S. Cl. 136/255; 438/72; 438/69; 257/E31.126; 257/E31.127

(57) ABSTRACT

A tunneling layer is provided between a transparent conductive material and a p-doped semiconductor layer of a photovoltaic device. The tunneling layer is comprised of stoichiometric oxides which are formed when an upper surface of the transparent conductive material is subjected to one of the surface modification techniques of this disclosure. The surface modification techniques oxidize the dangling metal bonds of the transparent conductive material. The tunneling layer acts as a protective layer for the transparent conductive material. Moreover, the tunneling layer improves the interface between the transparent conductive material and the p-doped semiconductor layer. The improved interface that exists between the transparent conductive material and the p-doped semiconductor layer results in enhanced properties of the resultant photovoltaic device containing the same. In some embodiments, a high quality single junction solar cell can be provided by this disclosure that has a very well defined interface.

The present disclosure relates to photovoltaic devices, and more particularly to photovoltaic devices such as, for example, solar cells, including a tunneling layer located between a transparent conductive material and a p-doped semiconductor layer and a method of forming the same. The tunneling layer is a stochiometric oxygen rich transparent conductive material surface layer.

A photovoltaic device is a device that converts the energy of incident photons to electromotive force (e.m.f.). Typical photovoltaic devices include solar cells, which are configured to convert the energy in the electromagnetic radiation from the Sun to electric energy. Each photon has an energy given by the formula E=hν, in which the energy E is equal to the product of the Plank constant h and the frequency ν of the electromagnetic radiation associated with the photon.

A photon having energy greater than the electron binding energy of a matter can interact with the matter and free an electron from the matter. While the probability of interaction of each photon with each atom is probabilistic, a structure can be built with a sufficient thickness to cause interaction of photons with the structure with high probability. When an electron is knocked off an atom by a photon, the energy of the photon is converted to electrostatic energy and kinetic energy of the electron, the atom, and/or the crystal lattice including the atom. The electron does not need to have sufficient energy to escape the ionized atom. In the case of a material having a band structure, the electron can merely make a transition to a different band in order to absorb the energy from the photon.

The positive charge of the ionized atom can remain localized on the ionized atom, or can be shared in the lattice including the atom. When the positive charge is shared by the entire lattice, thereby becoming a non-localized charge, this charge is described as a hole in a valence band of the lattice including the atom. Likewise, the electron can be non-localized and shared by all atoms in the lattice. This situation occurs in a semiconductor material, and is referred to as photogeneration of an electron-hole pair. The formation of electron-hole pairs and the efficiency of photogeneration depend on the band structure of the irradiated material and the energy of the photon. In ease the irradiated material is a semiconductor material, photogeneration occurs when the energy of a photon exceeds the band gap energy, i.e., the energy difference of a band gap of the irradiated material.

The direction of travel of charged particles, i.e., the electrons and holes, in an irradiated material is sufficiently random. Thus, in the absence of any electrical bias, photogeneration of electron-hole pairs merely results in heating of the irradiated material. However, an external field can break the spatial direction of the travel of the charged particles to harness the electrons and holes formed by photogeneration.

One exemplary method of providing an electric field is to form a p-i-n junction around the irradiated material. As negative charges accumulate in the p-doped region and positive charges accumulate in the n-doped region, an electric field is generated from the direction of the n-doped region toward the p-doped region. Electrons generated in the intrinsic region drift towards the n-doped region due to the electric field, and holes generated in the intrinsic region drift towards the p-doped region. Thus, the electron-hole pairs are collected systematically to provide positive charges at the p-doped region and negative charges at the n-doped region. The p-i-n junction forms the core of this type of photovoltaic device, which provides electromotive force that can power any device connected to the positive node at the p-doped region and the negative node at the n-doped region.

Among solar cell devices, amorphous silicon based solar cells are gaining attention due to their appealing cost effectiveness. Although, the overall efficiency is still less than crystalline silicon and the degradation in performance due to prolong light exposure poses a challenge, recent development efforts promise a bright future for this technology. Amorphous Si based solar cell device performance is highly dependent on the quality of the interface between the transparent conductive oxide (TCO) and the underlying p-type silicon film. ZnO:Al, InSnO₂, and SnO:F are some known examples of TCO materials that can be employed in amorphous solar cell devices as the front contact of the cell. Such TCO materials are prone to hydrogen damage during the deposition of the p-type silicon layer. Such damage, in turn, negatively impacts the current density and hence the efficiency of the solar cell device.

### BRIEF SUMMARY

A tunneling layer is provided between a transparent conductive material and a p-doped semiconductor layer of a photovoltaic device. The tunneling layer of this disclosure is comprised of stoichiometric oxides which are formed when a surface portion of the underlying transparent conductive material is subjected to one of the surface modification techniques of this disclosure. It is observed that the tunneling layer of the present disclosure can be referred to as a stochiometric oxygen rich transparent conductive material surface layer.

The surface modification techniques described in this disclosure oxidize the dangling metal bonds located at the upper surface of the transparent conductive material. The tunneling layer, which has a thickness on the order of 10 nm or less, acts as a protective layer for the underlying transparent conductive material; the aforementioned thinness of the tunneling layer ensures that the tunneling layer has conductive, not insulating, properties. Moreover, the tunneling layer improves the interface between the transparent conductive material and the p-doped semiconductor layer. The improved interface that exists between the transparent conductive material and the p-doped semiconductor layer results in enhanced properties of the resultant photovoltaic device containing the same. In some embodiments, a high quality single junction solar cell can be provided by this disclosure that has a very well defined interface.

According to an aspect of the present disclosure, a photovoltaic device is provided, which includes a p-doped semiconductor layer, a tunneling layer comprised of stoichiometric oxides located on an upper surface of the p-doped semiconductor layer, and a transparent conductive material located on an upper surface of the tunneling layer.

According to another aspect of the present disclosure, a method of forming a photovoltaic device is provided. The method includes providing a structure including a transparent conductive material on a surface of a substrate. An upper surface of the transparent conductive material is exposed to an oxygen based surface treatment that oxidizes metal dangling bonds present on the upper surface of the transparent conductive material forming a tunneling layer comprised of stoichiometric oxides. A p-doped semiconductor layer is formed on an upper surface of the tunneling layer.

In one embodiment, the oxygen based surface treatment includes a wet chemical treatment in which at least one oxygen-containing source material is employed. In another embodiment, the oxygen based surface treatment includes a deposition treatment, such as chemical vapor deposition (CVD) or plasma enhanced chemical vapor deposition (PECVD) in which at least one oxygen-containing source material is employed.

The term “oxygen-containing source material” as used for both embodiments mentioned above includes any material (solid, liquid and/or gas) that includes oxygen.

### BRIEF DESCRIPTION OF THE DRAWINGS

FIG. 1 is a pictorial representation (through a cross sectional view) depicting an initial structure that can be employed in forming a photovoltaic device in accordance with the present disclosure, the initial structure includes a substrate and a transparent conductive material located on a surface thereof; the surface of the transparent conductive material can be textured, which means the surface of transparent conductive material can be rough. The RMS value of the roughness can be in the range of few a nanometers to microns. The drawing does not represent true surface roughness of the transparent conductive material.

FIG. 2 is a pictorial representation (through a cross sectional view) depicting the initial structure of FIG. 1 after forming a tunneling layer comprised of stoichiometric oxides on an upper surface of the transparent conductive material.

FIG. 3 is a pictorial representation (through a cross sectional view) depicting the structure of FIG. 2 after forming a semiconductor material stack including, from bottom to top, a p-doped semiconductor layer, an intrinsic semiconductor layer and an n-doped semiconductor layer on an exposed surface of the tunneling layer.

FIG. 4 is a pictorial representation (through a cross sectional view) depicting the structure of FIG. 3 after forming a first back reflector layer on an exposed surface of the n-doped semiconductor layer and after forming a second back reflector layer on an exposed upper surface of the first back reflector layer.

FIG. 5 is a pictorial representation (through a cross sectional view) after rotating by 180°, i.e., flipping, the structure shown in FIG. 4 to provide a photovoltaic device in accordance with the present disclosure.

FIG. 6 is a comparative J-V curve (short circuit density, i.e., J_{SC}, mA/cm², vs. open circuit voltage, i.e., V_{OC}, V) on a 4 mm×4 mm single junction solar cell device prepared with and without a tunneling layer of this disclosure located between the transparent conductive material and the p-doped semiconductor layer.

### DETAILED DESCRIPTION

The present disclosure, which provides a photovoltaic device including a tunneling layer located between a transparent conductive material and a p-doped semiconductor layer and a method of forming such a device, will now be described in greater detail by referring to the following discussion and drawings that accompany the present application. It is observed that the drawings of the present application are provided for illustrative proposes and, as such, the drawings are not drawn to scale.

In the following description, numerous specific details are set forth, such as particular structures, components, materials, dimensions, processing steps and techniques, in order to provide an understanding of some aspects of the present disclosure. However, it will be appreciated by one of ordinary skill in the art that the various embodiments of the present disclosure may be practiced without these specific details. In other instances, well-known structures or processing steps have not been described in detail in order to avoid obscuring the disclosure.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

As stated above, the present disclosure provides a photovoltaic device and a method of forming the same. The photovoltaic device of the present disclosure includes a p-doped semiconductor layer, a tunneling layer located on an upper surface of the p-doped semiconductor layer, and a transparent conductive material located on an upper surface of the tunneling layer. The tunneling layer of this disclosure is comprised of stoichiometric oxides. The tunneling layer, which has a thickness on the order of 10 nm or less, acts as a protective layer for the transparent conductive material. Because of the thin nature of the tunneling layer, the tunneling layer has conductive, not insulating, properties. Moreover, the tunneling layer improves the interface between the transparent conductive material and the p-doped semiconductor layer. The improved interface that exists between the transparent conductive material and the p-doped semiconductor layer results in enhanced properties of the resultant photovoltaic device containing the same. In some embodiments, a high quality single junction solar cell can be provided by this disclosure that has a very well defined interface.

The method that can be employed in forming the above mentioned photovoltaic device includes providing a structure including a transparent conductive material on a surface of a substrate. An upper surface of the transparent conductive material is exposed to an oxygen based surface treatment that oxidizes metal dangling bonds present on the upper surface of the transparent conductive material forming a tunneling layer comprised of stoichiometric oxides. A p-doped semiconductor layer is formed on an upper surface of the tunneling layer.

Throughout this disclosure an element is “optical transparent” if the element is transparent in the visible electromagnetic spectral range having a wavelength from 400 nm to 800 nm.

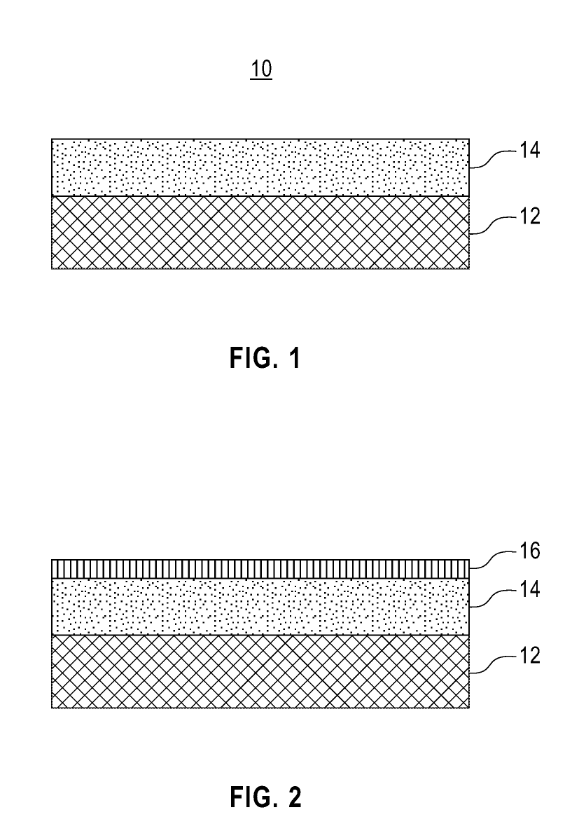

The above aspects of the present application, which are illustrated within the drawings of the present application, are now described in greater detail. Reference is first made to FIG. 1 which illustrates an initial structure 10 that can be employed in one embodiment of the present disclosure. The initial structure 10 includes a transparent conductive material 14 located on an exposed surface of substrate 12.

The transparent conductive material 14 typically includes an upper surface that is textured. The textured upper surface is not specifically labeled in the drawings of the present application. A textured (i.e., specially roughened) surface is used in solar cell applications to increase the efficiency of light absorption. The textured surface decreases the fraction of incident light lost to reflection relative to the fraction of incident light transmitted into the cell since photons incident on the side of an angled feature will be reflected onto the sides of adjacent angled features and thus have another chance to be absorbed. Moreover, the textured surface increases internal absorption, since light incident on an angled surface will typically be deflected to propagate through the device at an oblique angle, thereby increasing the length of the path taken to reach the device's back surface, as well as making it more likely that photons reflected from the device's back surface will impinge on the front surface at angles compatible with total internal reflection and light trapping. The texturing of the upper surface of the transparent conductive material 14 can be performed utilizing conventional techniques well known in the art. Typically, the texturing is achieved utilizing a hydrogen based wet etch chemistry, such as, for example, etching in HCl. In some embodiments, the textured upper surface can be achieved during formation, i.e., deposition, of the transparent conductive material 14.

The initial structure 10 can be commercially purchased from known suppliers including, but not limited to, Asahi Glass Company. Alternatively, the initial structure 10 can be formed by depositing the transparent conductive material 14 on a surface of substrate 12. The depositing of the transparent conductive material 14 on a surface of substrate 12 can include, but is not limited to, chemical vapor deposition (CVD), plasma enhanced chemical vapor deposition (CVD), physical vapor deposition (PVD), and metalorgano chemical vapor deposition (MOCVD). As mentioned above, the upper surface of the transparent conductive material 14 is textured. Texturing can be achieved either during deposition of the transparent conductive material 14 or after deposition utilizing a wet chemical etching process as mentioned above.

The substrate 12 of the initial structure 10 is a material layer that provides mechanical support to the photovoltaic device. The substrate 12 is typically transparent in the range of electromagnetic radiation at which photogeneration of electrons and holes occur within the photovoltaic device. When the photovoltaic device of the present disclosure is to be used as a solar cell, the substrate 12 can be optically transparent. In one embodiment, the substrate 12 can be a glass substrate. In another embodiment, substrate 12 can be selected from, but not limited to, plastic and/or other transparent polymer substrates. The thickness of the substrate 12 may vary. Typically, and in one embodiment of the present disclosure, substrate 12 has a thickness from 50 microns to 3 mm. In other embodiments of the present application, substrate 12 can have a thickness that is less than 50 microns and/or greater than 3 mm.

The transparent conductive material 14 of the initial structure 10 includes a conductive material that is transparent in the range of electromagnetic radiation at which photogeneration of electrons and holes occur within the photovoltaic device structure. If the photovoltaic device is employed as a solar cell, the transparent conductive material 14 can be optically transparent. In such an embodiment, the transparent conductive material 14 can include a transparent conductive oxide such as, but not limited to, a fluorine-doped tin oxide (SnO₂:F), an aluminum-doped zinc oxide (ZnO:Al), tin oxide (SnO) and indium tin oxide (InSnO₂, or ITO for short). In one embodiment, the transparent conductive material 14 is SnO₂:F.

The thickness of the transparent conductive material 14 may vary depending on the type of transparent conductive material employed as well as the technique that was used in forming the transparent conductive material. Typically, and in one embodiment, the thickness of the transparent conductive material 14 is from 300 nm to 3 microns. Other thicknesses, including those less than 300 nm and/or greater than 3 microns can also be employed.

Referring now to FIG. 2, there is illustrated the initial structure 10 of FIG. 1 after forming a tunneling layer 16 on an exposed surface of the transparent conductive material 14. The tunneling layer 16 of the present disclosure, which acts as a protective layer for the transparent conductive material 14, is comprised of stoichiometric oxides. That is, the tunneling layer 16 has a well defined ratio of oxygen atoms therein. The tunneling layer 16 typically has a thickness that is less than 10 nm, with a thickness from 1 nm to 5 nm being more typical. It is observed that at these thickness values, the tunneling layer 16 is not an insulator, but instead it has conductive properties similar to that of the transparent conductive material 14.

The tunneling layer 16 is formed when an upper surface of the transparent conductive material 14 is exposed to an oxygen based surface treatment that oxidizes metal dangling bonds present on the upper surface of the transparent conductive material 14 forming tunneling layer 16 that is comprised of stoichiometric oxides.

In one embodiment, the oxygen based surface treatment includes a wet chemical treatment in which at least one oxygen-containing source material is employed. In another embodiment, the oxygen based surface treatment includes a deposition treatment, such as chemical vapor deposition (CVD) or plasma enhanced chemical vapor deposition (PECVD) in which at least one oxygen-containing source material is employed.

The term “oxygen-containing source material” as used for both embodiments mentioned above includes any material (solid, liquid and/or gas) that includes oxygen. Examples of oxygen-containing source materials that can be employed in either embodiment include, but are not limited to, oxygen, ozone, N₂O and mixtures thereof. The oxygen-containing source material can be used neat or can be admixed with an inert gas such as, for example, He, Ar, Ne and/or Xe. When the oxygen-containing source material is used in an admixture, the content of the oxygen-containing source material is typically from 1% to 99%, based on 100% of the admixture.

The exposure of the upper surface of the transparent conductive material 14 to the oxygen-containing source material may be performed at a temperature from 20° C. to 500° C., with a temperature of exposure from 20° C. to 250° C. being more typical. The duration of the exposure of the upper surface of the transparent conductive material 14 to the oxygen-containing source material may vary depending on the technique that is specifically employed as well as the material of the transparent conductive material 14 that is being exposed to the oxygen-containing source material. Typically, the duration of the exposure of the transparent conductive material 14 to the oxygen-containing source material is from 5 seconds to 20 minutes, with a duration from 30 seconds to 10 minutes being more typical.

In one embodiment of the present disclosure, the exposure of the upper surface of the transparent conductive material 14 to the oxygen-containing source material includes a wet chemical treatment using hydrogen-based chemistry such as, for example, HCl, HF or a combination thereof, followed by treatment with an ozonated solution. In one embodiment, the ozonated solution can be obtained by passing ozone over H₂O. In such an embodiment, the upper surface of the transparent conductive material 14 is first treated with a hydrogen-based material and thereafter the ozonated solution can be typically applied directly to the upper surface of the hydrogen-treated transparent conductive material, by utilizing any coating method well known to those skilled in the art. Typically, the contacting is performed by submerging the substrate or dipping the substrate in the solution.

In another embodiment of the present disclosure, the exposure of the upper surface of the transparent conductive material 14 to the oxygen-containing source material includes a CVD or PECVD deposition treatment in which an oxygen plasma is employed as the oxygen-containing source material.

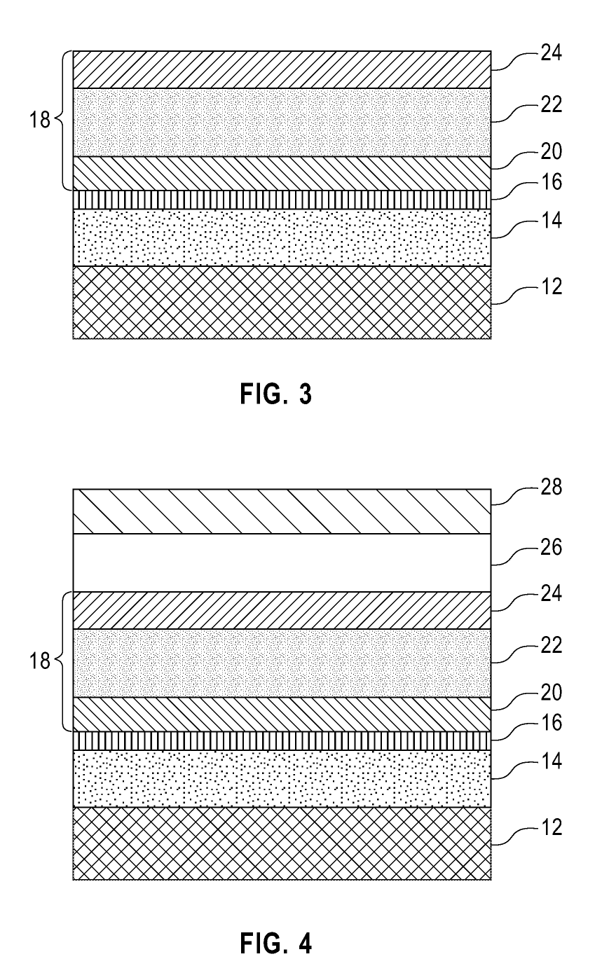

Referring to FIG. 3, there is shown the structure of FIG. 2 after forming a semiconductor material stack 18 on an exposed surface of the tunneling layer 16. The semiconductor material stack 18 includes, from bottom to top, a p-doped semiconductor layer 20 located on the exposed surface of the tunneling layer 16, an intrinsic semiconductor layer 22 located on an exposed surface of the p-doped semiconductor layer 20, and an n-doped semiconductor layer 24 located on an exposed surface of the intrinsic semiconductor layer 22.

The p-doped semiconductor layer 20 includes an amorphous or microcrystalline p-doped semiconductor-containing material. In some cases, the p-doped semiconductor layer 20 can include a hydrogenated amorphous or microcrystalline p-doped semiconductor-containing material. The presence of hydrogen in the p-doped semiconductor layer 20 can increase the concentration of free charge carriers, i.e., holes, by delocalizing the electrical charges that are pinned to defect sites. In some preferred embodiments, the p-doped semiconductor layer 20 is an amorphous p-doped semiconductor-containing material that optional includes hydrogen therein.

The term “amorphous” denotes that the p-doped semiconductor-containing material lacks a specific crystal structure. The term “p-doped semiconductor-containing material” denotes any material that has semiconductor properties such as, for example, Si, Ge, SiGe, SiC, SiGeC, any Si based semiconductors, which includes a p-type dopant therein. In one embodiment, the p-doped semiconductor layer 20 is comprised of Si. In another embodiment, the p-doped semiconductor layer 20 is comprised of Ge. In a further embodiment, the p-doped semiconductor layer 20 is comprised of SiGe.

The microcrystalline p-doped hydrogenated semiconductor-containing material can be a microcrystalline p-doped hydrogenated silicon-carbon alloy. In this case, a carbon-containing gas can be flown into the processing chamber during deposition of the microcrystalline p-doped hydrogenated silicon-carbon alloy. The atomic concentration of carbon in the microcrystalline p-doped hydrogenated silicon-carbon alloy of the p-doped semiconductor layer can be from 1% to 90%, and preferably from 10% to 28%. In this case, the band gap of the p-doped semiconductor layer 20 can be from 1.7 eV to 2.1 eV.

As mentioned above, the p-doped semiconductor layer 20 includes a p-type dopant therein. The concentration of p-type dopant within the p-doped semiconductor layer 20 may vary depending on the ultimate end use of the photovoltaic device and the type of dopant atom being employed. In one embodiment, the p-doped semiconductor layer 20 has a p-type dopant concentration from 1e1.5 atoms/cm³ to 1e17 atoms/cm³, with a p-type dopant concentration from 5e15 atoms/cm³ to 5e16 atoms/cm³ being more typical.

The p-doped semiconductor layer 20 of the semiconductor material stack 18 can be formed utilizing any epitaxial growth process that is well known to those skilled in the art. In one embodiment, the epitaxial growth process includes an in-situ doped epitaxial growth process in which the dopant atom is introduced with the semiconductor precursor source material, e.g., a silane, during the formation of the p-doped semiconductor layer. In another embodiment, an epitaxial growth process is used to form an undoped semiconductor layer, and thereafter the dopant can be introduced using one of ion implantation, gas phase doping, liquid solution spray/mist doping, and/or out-diffusion of a dopant atom from an overlying sacrificial dopant material layer that can be formed on the undoped semiconductor material, and removed after the out-diffusion process.

A hydrogenated p-doped semiconductor-containing material can be deposited in a process chamber containing a semiconductor precursor source material gas and a carrier gas. To facilitate incorporation of hydrogen in the hydrogenated p-doped semiconductor-containing material, a carrier gas including hydrogen can be employed. Hydrogen atoms in the hydrogen gas are incorporated into the deposited material to form an amorphous or microcrystalline hydrogenated p-doped semiconductor-containing material of the p-doped semiconductor layer 20.

The thickness of the p-doped semiconductor layer 20 can vary depending on the conditions of the epitaxial growth process employed. Typically, the p-doped semiconductor layer 20 has a thickness from 3 nm to 30 nm.

The intrinsic semiconductor layer 22 can include any intrinsic semiconductor-containing material that is typically, but not necessarily always hydrogenated. The intrinsic semiconductor-containing material can be amorphous or microcrystalline. Typically, the intrinsic semiconductor-containing material is amorphous. The thickness of the intrinsic semiconductor layer 22 depends on the diffusion length of electrons and holes in the intrinsic semiconductor-containing material. Typically, the thickness of the intrinsic semiconductor layer 22 is from 100 nm to 1 micron, although lesser and greater thicknesses can also be employed.

The intrinsic semiconductor layer 22 can include the same or different, typically the same, semiconductor material as that of the p-doped semiconductor layer 20. The intrinsic semiconductor layer 22 is formed utilizing any conventional epitaxial growth process including any conventional semiconductor precursor source material. In some embodiments, the p-type semiconductor material 20 and the intrinsic semiconductor layer 22 can be formed without breaking vacuum between the two deposition steps. In some embodiments, the intrinsic hydrogenated semiconductor-containing material is deposited in a process chamber containing a semiconductor precursor source gas and a carrier gas including hydrogen. Hydrogen atoms in the hydrogen gas within the carrier gas are incorporated into the deposited material to form the intrinsic hydrogenated semiconductor-containing material of the intrinsic semiconductor layer 22.

The n-doped semiconductor layer 24 of semiconductor material stack 18 includes an n-doped semiconductor-containing material, i.e., a semiconductor-containing material including an n-type dopant therein. The term “n-type dopant” is used throughout the present disclosure to denote an atom from Group VA of the Periodic Table of Elements including, for example, P, As and/or Sb. The concentration of n-type dopant within the n-doped semiconductor layer 24 may vary depending on the ultimate end use of the photovoltaic device and the type of dopant atom being employed. In one embodiment, the n-type semiconductor layer 24 typically has an n-type dopant concentration from 1e16 atoms/cm³ to 1e22 atoms/cm³, with an n-type dopant concentration from 1e19 atoms/cm³ to 1e21 atoms/cm³ being more typical. The sheet resistance of the n-type semiconductor layer 24 is typically greater than 50 ohm/sq, with a sheet resistance range of the n-type semiconductor layer 24 from 60 ohm/sq to 200 ohm/sq being more typical.

In some embodiments, the n-doped semiconductor layer 24 can be a hydrogenated material, in which case an n-doped hydrogenated semiconductor-containing material is deposited in a process chamber containing a semiconductor-material-containing reactant gas a carrier gas including hydrogen. The n-type dopants in the n-doped semiconductor layer 24 can be introduced by in-situ doping. Alternately, the n-type dopants in the n-doped semiconductor layer 24 can be introduced by subsequent introduction of dopants employing any method known in the art including those methods mentioned above in introducing a p-type dopant into p-doped semiconductor layer 20. In some embodiments, the vacuum used in forming the intrinsic semiconductor layer 22 is not broken when forming the n-doped semiconductor layer 24.

The n-doped semiconductor layer 24 can be amorphous or microcrystalline. The thickness of the n-doped semiconductor layer 24 can be from 6 nm to 26 nm, although lesser and greater thicknesses can also be employed.

The n-doped semiconductor layer 24 can include the same or different semiconductor materials as that of semiconductor layers 20 and 22. Typically, n-doped semiconductor layer 24, intrinsic semiconductor layer 22, and p-doped semiconductor layer 20 are each comprised of a same semiconductor material. In one embodiment, each of semiconductor layers 20, 22 and 24 are comprised of Si, Ge or a SiGe alloy. Typically, each of semiconductor layers 20, 22 and 24 are comprised of an amorphous semiconductor material, such as amorphous Si, that can be optionally hydrogenated.

Referring now to FIG. 4, there is illustrated the structure of FIG. 3 after forming a first back reflector layer 26 on an exposed surface of the n-doped semiconductor layer 24 and after forming a second back reflector layer 28 on an exposed upper surface of the first back reflector layer 26.

The first back reflector layer 26 can include any conductive material including a transparent conductive material that is transparent in the range of electromagnetic radiation at which photogeneration of electrons and holes occur within the photovoltaic device structure. If the photovoltaic device is employed as a solar cell, the first back reflector layer 26 can be optically transparent. For example, the first back reflector layer 26 can include one of the transparent conductive oxides mentioned above and which can also be formed utilizing one of the deposition steps mentioned in regard to forming the transparent conductive material 14. Since such transparent conductive oxide materials are n-type materials, the contact between the first back reflector layer 26 and the n-doped semiconductor layer 24 is Ohmic, and as such, the contact resistance between the first back reflector layer 26 and the n-doped semiconductor layer 24 is negligible.

The thickness of the back reflector layer 26 may vary depending on the type of conductive material employed. The thickness of the back reflector layer 26 can be from 25 nm to 250 nm, although lesser and greater thicknesses can also be employed.

The second back reflector layer 28 includes a metallic material. Preferably, the metallic material has a high reflectivity in the range of electromagnetic radiation at which photogeneration of electrons and holes occur within the photovoltaic device structure. The metallic material can include silver, aluminum, or an alloy thereof. The metallic material used in forming the second back reflector layer 28 can include applying a metallic paste to the exposed surface of the first back reflector layer 26. The metallic paste, which includes any conductive paste such as Al paste, Ag paste or AlAg paste, is formed utilizing conventional techniques that are well known to those skilled in the art of solar cell fabrication. After applying the metallic paste, the metallic paste is heated to a sufficiently high temperature which causes the metallic paste to flow and form a metallic layer on the applied surface of the first back reflector layer 26. In one embodiment, and when an Al or Ag paste is employed, the Al or Ag paste is heated to a temperature from 700° C. to 900° C. which causes the Al or Ag paste to flow and form an Al or Ag layer. The back side metallic film 16 that is formed from the metallic paste serves as a conductive back surface field and a backside electrical contact of a solar cell.

The thickness of the second back reflector layer 28 can be from 100 nm to 1 micron, although lesser and greater thicknesses can also be employed.

In some embodiments (not shown), the first back reflector layer 26 can be omitted and the second back reflector layer 28 is formed directly on the exposed surface of the n-doped semiconductor layer 24.

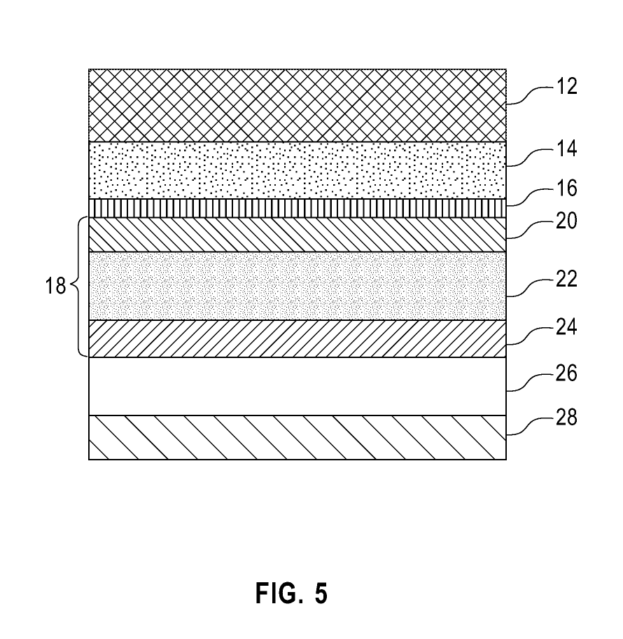

Referring now to FIG. 5, there is illustrated the structure of FIG. 4 after rotating that structure 180°. That is, the structure shown in FIG. 4 is flipped such that the substrate 10 represents the upper most layer of the device and the second back surface reflector layer 28 represents the bottom most surface of the device.

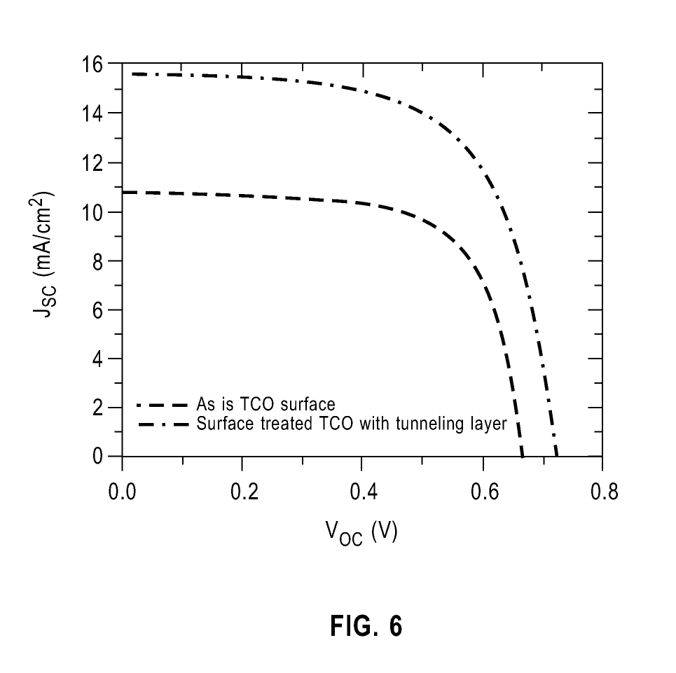

It is observed that tunneling layer 16 which is a stoichiometric oxygen rich transparent conductive material layer, described above improves the interface between the transparent conductive material 14 and the p-doped semiconductor layer 20. The improved interface that exists between the transparent conductive material 14 and the p-doped semiconductor layer 20 results in enhanced properties of the resultant photovoltaic device containing the same. In some embodiments, a high quality single junction solar cell can be provided by this disclosure that has a very well defined interface. FIG. 6 is a comparative J-V curve (short circuit density, i.e., J_{SC}, mA/cm², vs. open circuit voltage, i.e., V_{OC}, V) on a 4 mm×4 mm single junction solar cell device prepared with and without a tunneling layer of this disclosure located between the transparent conductive material and the p-doped semiconductor layer. The comparative J-V curve clearly illustrates the benefits in terms of a higher short circuit density that can be obtained when using the tunneling layer of the present disclosure, as compared to a photovoltaic device in which the tunneling layer is not present.

While the present disclosure has been particularly shown and described with respect to preferred embodiments thereof, it will be understood by those skilled in the art that the foregoing and other changes in forms and details can be made without departing from the spirit and scope of the present disclosure. It is therefore intended that the present disclosure not be limited to the exact forms and details described and illustrated, but fall within the scope of the appended claims.

What is claimed is:

1. A photovoltaic device comprising:
a p-doped semiconductor layer;
a tunneling layer comprised of stoichiometric oxides located on an upper surface of the p-doped semiconductor layer; and
a transparent conductive material located on an upper surface of the tunneling layer.

2. The photovoltaic device of claim 1 further comprising a substrate located on a surface of the transparent conductive material that is opposite said upper surface of the transparent conductive material including the tunneling layer.

3. The photovoltaic device of claim 2 wherein said substrate is optically transparent.

4. The photovoltaic device of claim 3 wherein said substrate is a glass substrate.

5. The photovoltaic device of claim 1 wherein said transparent conductive material is optically transparent.

6. The photovoltaic device of claim 5 wherein said transparent conductive material is selected from a fluorine-doped tin oxide (SnO₂:F), an aluminum-doped zinc oxide (ZnO:Al), tin oxide (SnO) and indium tin oxide (InSnO₂).

7. The photovoltaic device of claim 1 wherein said tunneling layer has a thickness of 10 nm or less.

8. The photovoltaic device of claim 1 wherein said tunneling layer is conductive.

9. The photovoltaic device of claim 1 wherein said p-doped semiconductor layer is an amorphous or microcrystalline p-doped semiconductor-containing material.

10. The photovoltaic device of claim 1 wherein said p-doped semiconductor layer has a p-type dopant concentration from 1 e15 atoms/cm³ to 1e17 atoms/cm³.

11. The photovoltaic device of claim 1 wherein said p-doped semiconductor layer includes a hydrogenated amorphous p-doped semiconductor-containing material.

12. The photovoltaic device of claim 1 further comprising an intrinsic semiconductor layer contacting said p-doped semiconductor layer, and an n-doped semiconductor layer contacting said intrinsic semiconductor layer.

13. The photovoltaic device of claim 12 wherein said intrinsic semiconductor layer includes a hydrogenated amorphous intrinsic semiconductor-containing material.

14. The photovoltaic device of claim 12 wherein said n-doped semiconductor layer includes hydrogenated n-doped amorphous semiconductor-containing material.

15. The photovoltaic device of claim 12 further comprising at least one back reflector layer located on said n-doped semiconductor layer.

16. A method of forming a photovoltaic device comprising:
providing a structure including a transparent conductive material on a surface of a substrate;
exposing an upper surface of the transparent conductive material to an oxygen based surface treatment that oxidizes metal dangling bonds present on the upper surface of the transparent conductive material forming a tunneling layer on said transparent conductive material, said tunneling layer 15 comprised of stoichiometric oxides; and
forming a p-doped semiconductor layer on an upper surface of the tunneling layer.

17. The method of claim 16 wherein said oxygen based surface treatment includes a wet chemical treatment in which at least one oxygen-containing source material is employed.

18. The method of claim 17 wherein said wet chemical treatment includes contacting the upper surface of the transparent conductive material with an ozonated solution.

19. The method of claim 16 wherein said oxygen based surface treatment includes a deposition treatment in which at least one oxygen-containing source material is employed.

20. The method of claim 19 wherein said deposition treatment includes CVD or PECVD using an oxygen plasma.

21. The method of claim 16 wherein said oxygen based surface treatment includes use of an oxygen-containing source material selected from oxygen, ozone, N₂O and mixtures thereof.

22. The method of claim 16 wherein said structure further includes a substrate located beneath the transparent conductive material.

23. The method of claim 16 further comprising forming an intrinsic semiconductor layer on an exposed surface of the p-doped semiconductor layer, and forming an n-doped semiconductor on an exposed surface of the intrinsic semiconductor layer.

24. The method of claim 23 further comprising at least one back reflector layer located on said n-doped semiconductor layer.

25. The method of claim 16 wherein said transparent conductive material is an optical transparent conductive oxide material.
